(19) United States
(12) Patent Application Publication
(10) Pub. No.: US 2013/0247953 A1
(43) Pub. Date: Sep. 26, 2013

(54) ELECTRODE MATERIALS AND CONFIGURATIONS FOR THERMOELECTRIC DEVICES

(71) Applicants: Andrew Muto, Elmira, NY (US); Gang Chen, Carlisle, MA (US); Zhifeng Ren, Newton, MA (US)

(72) Inventors: Andrew Muto, Elmira, NY (US); Gang Chen, Carlisle, MA (US); Zhifeng Ren, Newton, MA (US)

(73) Assignees: Trustees of Boston College, Chestnut Hill, MA (US); Massachusetts Institute of Technology, Cambridge, MA (US)

(21) Appl. No.: 13/428,971

(22) Filed: Mar. 23, 2012

(51) Int. Cl. H01L 35/18; H01L 35/14; H01L 35/28

(52) U.S. Cl. 136/240; 136/200; 136/236.1

(57) ABSTRACT

Thermoelectric devices and associated materials and assembly methods are generally described. Certain aspects relate to electrode materials and electrode configurations for use in thermoelectric devices. In some embodiments, the inventive thermoelectric devices comprise electrodes comprising silicon, such as silicides of cobalt, iron, and/or nickel. Such electrode materials can be useful for making electrical contact with a wide variety of thermoelectric materials, including skutterudite materials. The thermoelectric devices described herein can be used to convert applied voltages to thermal gradients and or to convert thermal gradients to electricity.

### GOVERNMENT SPONSORSHIP

This invention was made with government support under Grant Nos. DE-SC0001299 and DE-FG02-09ER46577 awarded by the Department of Energy. The government has certain rights in this invention.

### TECHNICAL FIELD

Electrode materials and electrode configurations for thermoelectric devices are generally described.

### BACKGROUND

The thermoelectric effect refers to the direct conversion of temperature gradients to electric voltages, and vice versa. A large amount of research has focused on constructing thermoelectric devices that take advantage of the thermoelectric effect. For example, thermoelectric devices have been developed that produce voltages when a temperature gradient is applied across one or more thermoelectric materials. The process of inducing a voltage by applying a temperature gradient along a material is commonly referred to as the Seebeck effect. Such thermoelectric devices can be used, for example, as heat engines, converting thermal gradients (e.g., in geothermal heating systems, solar heating systems, and the like) into electricity.

Thermoelectric devices can also be used to create temperature gradients when voltages are applied across them. The process of generating a temperature gradients via the application of a voltage across a material is commonly referred to as the Peltier effect. Such thermoelectric devices can be used to provide, for example, localized cooling. As one particular example, Peltier coolers can be used to provide going to areas that are difficult to reach with conventional cooling systems, such as microfluidic channels.

Thermoelectric devices are appealing because they have no moving parts, are highly reliable, have high power densities, and are scalable in size. They can be used to improve the overall efficiency of many systems (e.g., motor vehicles, solar thermal power systems, HVAC systems, industrial manufacturing systems) by converting waste heat into usable electricity. However, the efficiencies of many current systems are limited by the materials and manufacturing techniques used to make them. Accordingly, improved materials and construction techniques for thermoelectric devices are desirable.

### SUMMARY

Electrode materials and electrode configurations for use in thermoelectric devices are provided. The subject matter of the present invention involves, in some cases, interrelated products, alternative solutions to a particular problem, and/or a plurality of different uses of one or more systems and/or articles.

In one set of embodiments, a thermoelectric device is provided. In certain embodiments, the thermoelectric device comprises an electrode material comprising silicon and a thermoelectric material in electronic communication with the electrode material, wherein the absolute value of the Seebeck coefficient of the thermoelectric material is at least about 10 μV/K at at least one temperature lower than about 600° C.

In some embodiments, the thermoelectric device comprises an electrode material comprising silicon and a thermoelectric material in electronic communication with the electrode material, wherein the thermoelectric material exhibits a Thermoelectric Figure of Merit of at least about 0.5 at at least one temperature lower than about 600° C.

In certain embodiments, the thermoelectric device comprises an electrode material comprising silicon and a thermoelectric material comprising a skutterudite material in electronic communication with the electrode material.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIG. 1 is a cross-sectional schematic illustration of an exemplary thermoelectric device;

FIGS. 2A-2B are cross-sectional schematic illustrations of thermoelectric devices, according to some embodiments;

FIG. 3 is, according to certain embodiments, a cross-sectional schematic illustration of a thermoelectric device;

FIG. 4 is a cross-sectional schematic illustration showing a press apparatus used to bond thermoelectric material to electrode material;

FIGS. 5A-5B are plots of temperature and pressure as a function of time, outlining the pressing conditions for p-type and n-type thermoelectric leg fabrication, according to one set of embodiments;

FIGS. 6A-6B are, according to certain embodiments, plots of bulk resistivity and contact resistance for samples in which thermoelectric material was bonded with electrode material;

FIGS. 7A-7B are exemplary cross-sectional schematic diagrams of inline device measurement systems used to test thermoelectric materials;

FIGS. 8A-8D are, according to some embodiments, plots illustrating properties of an n-type thermoelectric material;

FIGS. 9A-9B are plots of ZT and efficiency as a function of temperature, according to one set of embodiments;

FIGS. 10A-10D are, according to certain embodiments, plots illustrating properties of a p-type thermoelectric material;

FIGS. 11A-11B are plots of ZT and efficiency as a function of temperature, according to some embodiments;

FIGS. 12A-12B are plots of power as a function of electrical current, according to certain embodiments; and

FIGS. 13A-13B are, according to one set of embodiments, plots of conversion efficiency as a function of current.

### DETAILED DESCRIPTION

Thermoelectric devices and associated materials and assembly methods are generally described. Certain aspects relate to electrode materials and electrode configurations for use in thermoelectric devices. In some embodiments, the inventive thermoelectric devices comprise electrodes comprising silicon, such as silicides of cobalt, chromium, iron, and/or nickel. Such electrode materials can be useful for making electrical contact with a wide variety of thermoelectric materials, including skutterudite materials. The thermoelectric devices described herein can be used to convert applied voltages to thermal gradients and or to convert thermal gradients to electricity.

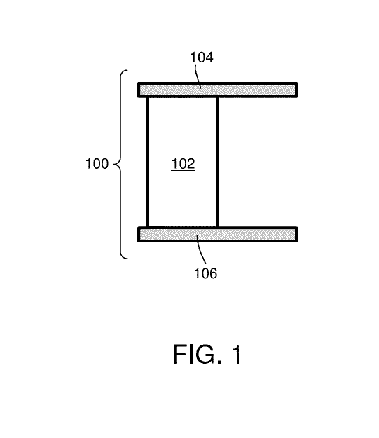

FIG. 1 is a schematic illustration of an exemplary thermoelectric device 100, according to one set of embodiments. In FIG. 1, thermoelectric device 100 comprises thermoelectric material 102. Thermoelectric device 100 also comprises electrode material 104 in electronic communication with thermoelectric material 102. Thermoelectric device 100 of FIG. 1 also includes a second electrode material 106 in electronic communication with thermoelectric material 102.

As used herein, a first material and a second material are in “electronic communication” with each other when they are in direct contact or when they are arranged such that at least one pathway can be traced from the first material to the second material such that the pathway passes only through electrically conductive materials. In certain embodiments, two articles are in electronic communication with each other when at least one pathway can be traced between the articles that passes only through materials having an electrical resistivity of less than about 1×10⁻⁵ ohm-m, less than about 1×10⁻⁶ ohm-m, or less than about 1×10⁻⁷ ohm-m at 20° C.

Two materials can be in electronic communication with each other when they are in direct contact. Accordingly, in certain embodiments, at least a portion of the electrode material is in direct contact with at least a portion of the thermoelectric material. In FIG. 1, for example, electrode materials 104 and 106 are in direct contact with thermoelectric material 102.

Two materials can also be in electronic communication with each other when one or more electrically conductive materials are positioned between the two materials, as long as an electrically conductive pathway is maintained between the two materials. Accordingly, in certain embodiments, an intermediate material is positioned between at least a portion of the electrode material and at least a portion of the thermoelectric material (and, in some cases, one or more intermediate materials completely separates the electrode material from the thermoelectric material). For example, in certain embodiments, an intermediate material such as a diffusion barrier can be positioned between electrode material 104 and thermoelectric material 102 (and/or between electrode material 106 and thermoelectric material 102) in FIG. 1.

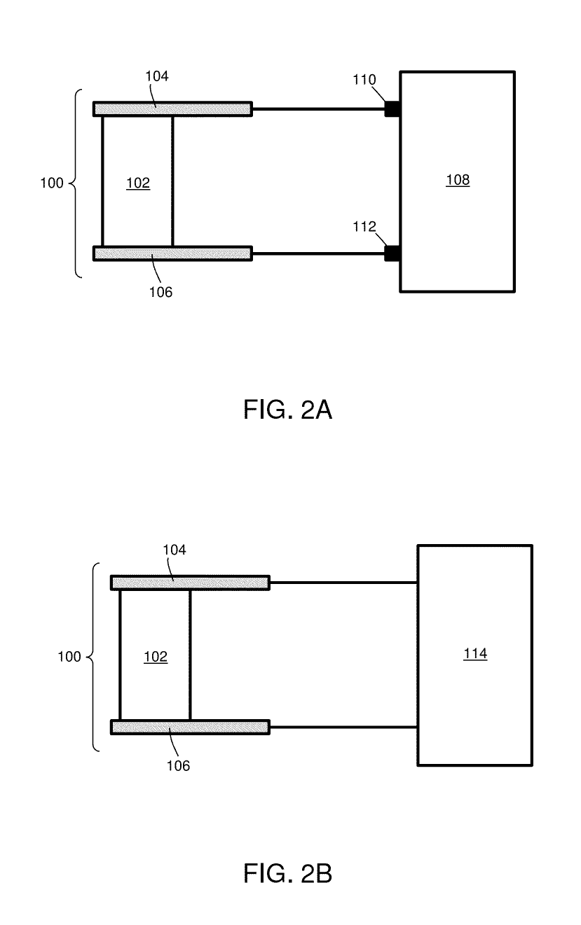

FIG. 2A is a schematic diagram illustrating ways in which thermoelectric device 100 can be operated to generate thermal gradients from a voltage source. In one set of embodiments, thermoelectric material 102 comprises an n-doped thermoelectric material. In some such embodiments, electrode material 104 can be electrically connected to positive terminal 110 of voltage source 108, and electrode material 106 can be connected to negative terminal 112 of voltage source 108. When connected in this fashion, electrons can be transported in the clockwise direction (i.e., from negative terminal 112 to electrode material 106, through thermoelectric material 102, and from electrode material 104 to positive terminal 110). This can result in the flow of heat from electrode material 106 to electrode material 104, resulting in the heating of electrode material 104 and the cooling of electrode material 106. When operated in this fashion, thermoelectric device 100 can provide local cooling near electrode material 106.

If, on the other hand, thermoelectric material 102 in FIG. 2A comprises a p-doped thermoelectric material, heat can be transported in the other direction. In some such embodiments, electron holes are transported in the counter-clockwise direction (i.e., from positive terminal 110 to electrode material 104, through thermoelectric material 102, and from electrode material 106 to negative terminal 112). This can result in local heating of electrode material 106 and local cooling of electrode material 104.

FIG. 2B is a schematic illustration showing ways in which thermoelectric device 100 can be operated to generate electricity from thermal gradients. In FIG. 2B, when thermoelectric material 102 comprise an n-doped thermoelectric material and a thermal gradient is applied across thermoelectric material 102 such that electrode material 106 is maintained at a relatively hot temperature and electrode material 104 is maintained at a relatively cold temperature, electrons are transported in a clockwise direction. Similarly, in FIG. 2B, when thermoelectric material 102 comprises an p-doped thermoelectric material and a thermal gradient is applied across thermoelectric material 102 such that electrode material 106 is maintained at a relatively hot temperature and electrode material 104 is maintained at a relatively cool temperature, electrons are transported in a counter-clockwise direction. In either case, the transport of electrons in FIG. 2B can be used to power external load 114.

Thermoelectric devices, such as those illustrated in FIGS. 1-2B, often produce high temperatures (e.g., temperatures of 500° C. to 600° C. or higher). One challenge associated with operating such devices is selecting electrical contact materials that are both sufficiently electrically conductive to serve as electrical contacts as well as sufficiently mechanically robust to avoid mechanical failure at high operating temperatures. In addition, it can be beneficial to select electrode materials that have thermal expansion coefficients that are close to those of the thermoelectric materials (i.e., such that the thermoelectric material and the electrode material are “thermally matched”). Selection of electrode materials with thermal expansion coefficients similar to those of the thermoelectric materials can ensure that the electrode materials do not expand substantially more or substantially less than the thermoelectric material when the device is heated or cooled, thereby inhibiting delamination, cracking, or other mechanical failure modes.

It has been unexpectedly discovered that electrode materials comprising silicon are both sufficiently electrically conductive and mechanically stable at high temperatures to serve as electrical contacts for a variety of thermoelectric materials, as described further below. In addition, it has been unexpectedly discovered that the use of such electrodes in thermoelectric systems can produce relatively high overall system efficiencies. In certain embodiments, inventive thermoelectric systems comprise an electrode material comprising silicon and at least one other element. In some embodiments, the electrode material comprises a silicon alloy. In some embodiments, the electrode material comprises silicon and at least one of cobalt, chromium, iron, and nickel. In certain embodiments, electrode materials comprising silicon can be arranged to be in electrical communication with electrodes comprising skutterudite materials to produce thermoelectric devices.

In certain embodiments, the electrode material comprises a silicide. Examples of silicides suitable for use in the electrode materials described herein include silicides of cobalt, chromium, nickel, and/or iron. Not wishing to be bound by any particular theory, it is believed that silicides of nickel, chromium, and iron can impart favorable properties due to the proximity of these elements to cobalt on the periodic table and due to the favorable thermal expansion characteristics of these silicides. In certain embodiments, the electrode material comprises silicon and at least one of cobalt, chromium, nickel, and iron (e.g., silicides of cobalt, chromium, nickel, or iron alone or in combination with each other), for example, in any of the ratios outlined herein. In certain embodiments, the electrode material comprises cobalt (e.g., a cobalt silicide).

In certain embodiments, the electrode material comprises CoₓSi_{y}, wherein x is from about 1 to about 3, and y is from about 1 to about 2. For example, the electrode material can comprise, in certain embodiments, at least one of CoSi, Co₂Si, Co₃Si, and CoSi₂. In certain embodiments, CoSi₂ can be used as an electrode material for bonding to an n-type thermoelectric material. Co₂Si can be used, in certain embodiments, as the electrode material for bonding with a p-type thermoelectric material.

In some embodiments, the electrode material comprises NiₓSi_{y}, wherein x is from about 1 to about 3, and y is from about 1 to about 2. For example, the electrode material can comprise at least one of Ni₂Si, Ni₃Si, and NiSi₂.

The electrode material comprises, in certain embodiments, FeₓSi_{y}, wherein x is from about 1 to about 5, and y is from about 1 to about 3. In some embodiments, the electrode material comprises at least one of Fe₂Si, Fe₃Si, Fe₅Si, FeSi, FeSi₂, FeSi_{2.3}, and Fe₅Si₃.

In certain embodiments, the electrode material comprises CrₓSi_{y}, wherein x is from about 1 to about 5, and y is from about 1 to about 3. For example, in some embodiments, the electrode material comprises at least one of CrSi, CrSi₂, Cr₃Si, and Cr₅Si₃.

In certain embodiments in which the electrode material comprises silicon, cobalt, chromium, iron, and/or nickel, those elements are present in a relatively large amount. In some embodiments, silicon, cobalt, chromium, iron, and/or nickel make up at least about 75%, at least about 85%, at least about 90%, at least about 95%, or at least about 99% (and, in some embodiments, up to substantially all) of the electrode material, by mass. For example, in some embodiments, the electrode material contains silicon and cobalt, and at least about 75% (or at least about 85%, at least about 90%, at least about 95%, or at least about 99%, and/or up to substantially all) of the electrode material, by mass, can be silicon and cobalt. In certain embodiments, the electrode material contains silicon, nickel, and iron, and at least about 75% (or at least about 85%, at least about 90%, at least about 95%, or at least about 99%, and/or up to substantially all) of the electrode material, by mass, can be silicon, nickel, and iron. Of course, other permutations of silicon and cobalt, chromium, iron, and/or nickel are possible, and in such permutations, the sum of the amount of silicon, cobalt, chromium, iron, and nickel within the electrode material can be at least about75% (or at least about 85%, at least about 90%, at least about 95%, or at least about 99%, and/or up to substantially all) of the electrode material, by mass.

Not wishing to be bound by any particular theory, it is believed that electrode materials with relatively large amounts of silicon, cobalt, chromium, iron, and/or nickel are capable of withstanding high temperatures and relatively fast heating rates, which make them particularly useful as electrode materials in thermoelectric devices. In addition, it is believed that such materials provide an especially good thermal expansion match (i.e., they expand and contract in response to temperature changes in a similar manner) when used with thermoelectric materials such as skutterudite materials. Of course, the use of electrode materials comprising silicon, cobalt, chromium, iron, and/or nickel is not limited to thermoelectric systems comprising skutterudite thermoelectric materials, and, in some embodiments, electrode materials comprising silicon, cobalt, chromium, iron, and/or nickel can be paired with non-skutterudite materials in a thermoelectric device.

A variety of thermoelectric materials can be used in association with the systems and methods described herein. In certain embodiments, the magnitudes of the Seebeck coefficients of the thermoelectric materials used herein can be relatively large. The Seebeck coefficient is an inherent physical property of a material and is known to those of ordinary skill in the art. Generally, the Seebeck coefficient (also sometimes referred to as the thermopower) is a measure of the magnitude of the thermoelectric voltage that is produced within a given material when a temperature gradient is established across that material. The Seebeck coefficient of a material can be negative or positive and generally has the units of unit voltage/unit temperature (e.g., microvolts per Kelvin (μV/K)). In addition, the Seebeck coefficient of a material usually varies with temperature.

In certain embodiments, the absolute value of the Seebeck coefficient of the thermoelectric materials described herein (e.g., thermoelectric material 102 in the figures) is at least about 10 μV/K, at least about 50 μV/K, or at least about 100 μV/K (and, in certain embodiments, up to about 500 μV/K, for example, from about 10 μV/K to about 500 μV/K, from about 50 μV/K to about 500 μV/K, or from about 100 μV/K to about 500 μV/K) at at least one temperature lower than about 600° C., at at least one temperature lower than about 500° C., or at at least one temperature lower than about 400° C. (e.g., at at least one temperature of from about 25° C. to about 600° C., from about 25° C. to about 500° C., or from about 25° C. to about 400° C.). In some embodiments, the absolute value of the Seebeck coefficient of the thermoelectric materials described herein is at least about 10 μV/K, at least about 50 μV/K, or at least about 100 μV/K (and, in certain embodiments, up to about 500 μV/K) at 25° C.

One of ordinary skill in the art would be capable of measuring the Seebeck coefficient of a particular material. For example, the Seebeck coefficient of a material can be calculated by measuring the voltage (e.g., using a voltimeter) and temperature (e.g., using a thermocouple) at each of two different points on a bar sample of the material. In such an experimental configuration, the Seebeck coefficient can be determined as:

$$S = - \frac{{V}_{1} - {V}_{2}}{{T}_{1} - {T}_{2}} = - \frac{Δ {V}_{12}}{Δ {T}_{12}} \qquad [ 1 ]$$

where V₁ is the voltage at the first point of the sample, V₂ is the voltage at the second point on the sample, T₁ is the temperature at the first point of the sample, and T₂ is the temperature at the second point of the sample. To correct for parasitic emf that may be present within the measurement loop, ΔV₁₂ can be measured as a function of ΔT₁₂ by varying the temperature difference and measuring the resulting voltage drop at a representative number of temperature gradients. The Seebeck coefficient can then be calculated as the slope of the plot of ΔV₁₂ as a function of ΔT₁₂ (by producing a linear plot with ΔV₁₂ on the y-axis and ΔT₁₂ on the x-axis and calculating the resulting slope using linear regression).

When measuring the Seebeck coefficient, the polarity of the voltimeter should be set such that it reads the voltage difference between the two measured points in the same direction as the temperature difference between the two measured points. One should also make sure that the voltages and temperatures are measured at the same locations on the sample. This can be accomplished, for example, by using thermocouple wires as both temperature measurement leads and as voltage probes. In such cases, contributions from the Seebeck effect of the thermocouple wires must be subtracted from the measured values, as is routinely done by those of ordinary skill in the art.

In certain embodiments, the thermoelectric materials described herein can be capable of exhibiting a relatively high Thermoelectric Figure of Merit. As used herein, the “Thermoelectric Figure of Merit” (abbreviated as ZT) of a material is a dimensionless number that is calculated as follows:

$$ZT = \frac{σ {S}^{2}}{λ} T \qquad [ 2 ]$$

wherein σ corresponds to the electrical conductivity of the material, S corresponds to the Seebeck coefficient of the material, λ corresponds to the thermal conductivity of the material, and T corresponds to the temperature of the material. The Thermoelectric Figure of Merit is a temperature-dependent intrinsic property of a material.

In certain embodiments, the thermoelectric materials described herein (e.g., thermoelectric material 102 in the figures) can exhibit a Thermoelectric Figure of Merit of at least about 0.5, at least about 0.75, at least about 1.0, at least about 1.25, at least about 1.5, at least about 1.75, or at least about 2.0 (and, in certain embodiments up to about 1.5 or up to about 3.0, for example, from about 0.5 to about 3.0, from about 0.75 to about 3.0, from about 1.0 to about 3.0, from about 0.5 to about 1.5, from about 0.75 to about 1.5, or from about 1.0 to about 1.5) at at least one temperature lower than about 600° C., lower than about 500° C., or lower than about 400° C. (e.g., at at least one temperature of from about 25° C. to about 600° C., from about 25° C. to about 500° C., or from about 25° C. to about 400° C.).

In certain embodiments, the thermoelectric materials described herein comprise at least one of cobalt, chromium, nickel, and iron. Not wishing to be bound by any particular theory, it is believed that thermoelectric materials comprising cobalt, chromium, nickel, and/or iron can be more easily thermally matched with electrode materials comprising cobalt, chromium, nickel, and/or iron. In certain embodiments, the thermoelectric material comprises cobalt. Optionally, a thermoelectric material comprising cobalt can be configured to be in electronic communication with an electrode comprising cobalt. In certain embodiments, the thermoelectric material comprises nickel. Optionally, a nickel-containing thermoelectric material can be configured to be in electronic communication with an electrode comprising nickel. In some embodiments, the thermoelectric material comprises iron. Optionally, an iron-containing thermoelectric material can be configured to be in electronic communication with an electrode comprising iron.

In some embodiments, the thermoelectric materials described herein comprise one or more metals typically found in skutterudite materials. In some embodiments, the thermoelectric material comprises at least one of As, P, and Sb. For example, in some embodiments, the thermoelectric material comprises Sb. In certain embodiments, the thermoelectric material comprises at least one of Yb, Nd, La, and Ce.

The thermoelectric material comprises, in certain embodiments, at least one of Co, Cr, Ni, and Fe. In some embodiments, the thermoelectric material comprises at least one of Yb, Nd, La, and Ce and at least one of Co, Cr, Ni, and Fe. In some embodiments, the thermoelectric material comprises Co.

In certain embodiments, the thermoelectric material comprises at least one of Yb, Nd, La, Ce, Pr, Pm, Sm, Eu, Gd, Tb, Dy, Ho, Er, Tm, and Lu.

The thermoelectric materials described herein can comprise a skutterudite material, in certain embodiments. Skutterudite materials are known to those of ordinary skill in the art, and generally refer to materials comprising at least one transition metal and at least one of phosphorus (P), antimony (Sb), and arsenic (As), usually with the molar ratio of the sum of the transition metal components to the sum of the phosphorus, antimony, and arsenic components relatively close to about 1:3.

In certain embodiments, the skutterudite can be a “filled” skutterudite, in which at least some of the spaces between the transition metal component(s) and the P, Sb, and/or As components are occupied by one or more rare earth metal atoms.

In certain embodiments, the thermoelectric materials described herein can comprise a skutterudite material with the following chemical formula:

(L)ₐ(M)_{b}(X)_{c} [3]

wherein:

L corresponds to a single element or a combination of elements selected from ytterbium (Yb), neodymium (Nd), lanthanum (La), cerium (Ce), praseodymium (Pr), promethium (Pm), samarium (Sm), europium (Eu), gadolinium (Gd), terbium (Tb), dysprosium (Dy), holmium (Ho), erbium (Er), thulium (Tm), and lutetium (Lu);

M corresponds to a single element or a combination of elements selected from scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), mercury (Hg), rutherfordium (Rf), dubnium (Db), seaborgium (Sg), bohrium (Bh), hassium (Hs), meitnerium (Mt), darmstadtium (Ds), roentgenium (Rg), and copernicium (Cn);

X corresponds to a single element or a combination of elements selected from phosphorus (P), antimony (Sb), and arsenic (As);

a is from 0 to about 1;

b is from about 3.5 to about 4.5; and

c is from about 11.5 to about 12.5.

In some such embodiments, b is from about 3.9 to about 4.1, or b is about 4. In certain such embodiments, c is from about 11.9 to about 12.1, or c is about 12.

In chemical formula [3], more than one L component, more than one M component, and/or more than one X component may be present, as long as the molar ratio of the sum of the L components to the sum of the M components to the sum of the X components is a:b:c (where a, b, and c can vary as outlined above). As one specific example, the thermoelectric material can comprise NdFe₃₅Co₀₅Sb₁₂, which includes 1 L component (Nd), 2 M components (Fe and Co), and 1 X component (Sb). In NdFe_{3.5}Co_{0.5}Sb₁₂, the molar ratio of the sum of the L components to the sum of the M components to the sum of the X components is 1:4:12 (i.e., 1:(3.5+0.5):12). In certain embodiments, the skutterudite material comprises Nd as an L component. In some embodiments, the skutterudite material comprises Fe as an M component. In some embodiments, the skutterudite material comprises Co as an M component. In some embodiments, the skutterudite material comprises Sb as an X component.

In one set of embodiments, the thermoelectric material comprises a skutterudite material with the following chemical formula:

NdₐFe_{b1}Co_{b2}Sb_{c} [4]

wherein a is from 0 to about 1, b1 is greater than 0, b2 is greater than 0, the sum of b1 and b2 is from about 3.5 to about 4.5, and c is from about 11.5 to about 12.5. In some such embodiments, b1 is from about 3.0 to about 4.0, from about 3.4 to about 3.6, or about 3.5. In some such embodiments, b2 is from about 0.1 to about 1.0, from about 0.4 to about 0.6, or about 0.5. In some such embodiments, a is from about 0.1 to about 1.0, from about 0.5 to about 1.0, or a is about 1. In some such embodiments, c is from about 11.9 to about 12.1, or c is about 12. For example, in certain embodiments, a thermoelectric material comprises NdFe_{3.5}Co_{0.5}Sb₁₂. In some such embodiments in which the thermoelectric material comprises a compound having chemical formula [4], the thermoelectric material is p-doped (e.g., it can be a “p-type” thermoelectric material).

In one set of embodiments, the thermoelectric material comprises a skutterudite material with the following chemical formula:

YbₐCo_{b}Sb_{c} [5]

wherein a is from 0 to about 1, b is from about 3.5 to about 4.5, and c is from about 11.5 to about 12.5. In some such embodiments, a is from about 0.1 to about 1.0, from about 0.5 to about 1.0, or a is about 1. In some such embodiments, b is from about 3.9 to about 4.1, or b is about 4. In some such embodiments, c is from about 11.9 to about 12.1, or c is about 12. For example, in certain embodiments, a thermoelectric material comprises Yb_{0.35}Co₄Sb₁₂. In some embodiments in which the thermoelectric material comprises a compound having chemical formula [5], the thermoelectric material is n-doped (e.g., it can be an “n-type” thermoelectric material).

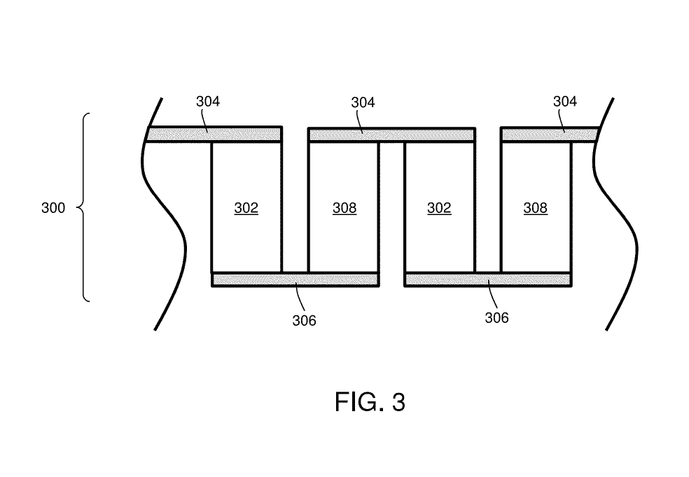

In certain embodiments, inventive thermoelectric devices can include a single type of thermoelectric material. For example, the thermoelectric devices illustrated in FIGS. 1-2B include a single thermoelectric material in electronic communication with electrode materials. In other embodiments, however, the thermoelectric device can include multiple thermoelectric materials. For example, in FIG. 3, thermoelectric device 300 includes multiple blocks of thermoelectric materials, including n-type thermoelectric materials 302 (e.g., any of the n-type thermoelectric materials described herein) and p-type thermoelectric materials 308 (e.g., any of the p-type thermoelectric materials described herein) connected in series. In FIG. 3, thermoelectric materials 302 are in electronic communication with thermoelectric materials 308 via electrode materials 304 and 306. In certain embodiments, electrode materials 304 and/or 306 can be in direct contact with thermoelectric materials 302 and/or 308. In some embodiments, one or more electrically conductive materials can be positioned between electrode materials 304 and/or 306 and thermoelectric materials 302 and/or 308. For example, in certain embodiments, one or more diffusion barriers can be positioned between an electrode material and a thermoelectric material in FIG. 3. For example, metals such as nickel, titanium, or alloys of these can be used in a diffusion barrier.

Arranging thermoelectric materials in series, for example as illustrated in FIG. 3, can provide a variety of advantages. For example, when exposing thermoelectric devices such as device 300 to a thermal gradient, the device can generate a relatively large amount of electrical current, relative to the amount of current that would be generated in a device including only a single thermoelectric material. Devices such as those illustrated in FIG. 3 can also be capable of generating a large amount of local cooling for a given amount of applied voltage, relative to devices including only a single thermoelectric material.

Thermoelectric materials and electrode materials can be arranged in electronic communication with each other using any suitable method. In certain cases, one or more intermediate materials (e.g., a metal-based solder) can be used to bond the thermoelectric material and the electrode material.

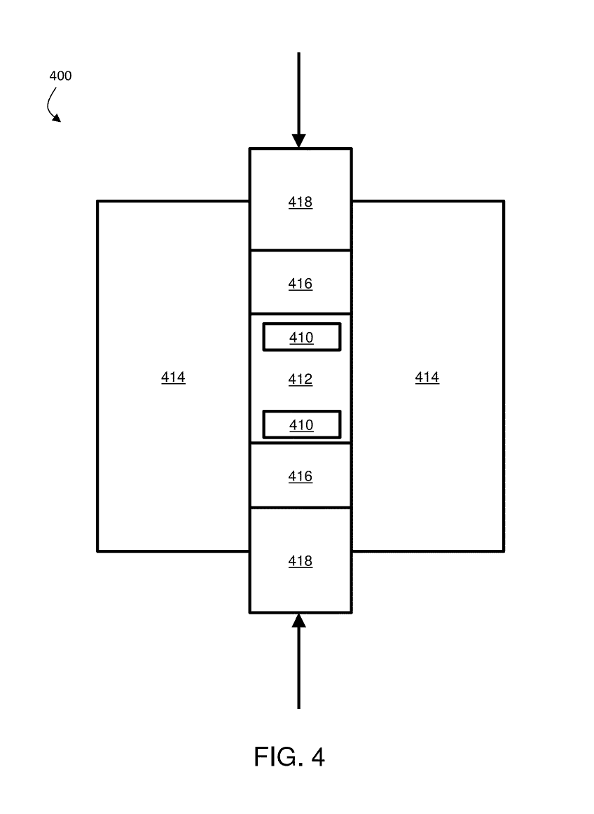

In some embodiments, the thermoelectric material and the electrode material can be bonded directly to each other. FIG. 4 is a cross-sectional schematic diagram illustrating a press apparatus 400 that can be used to directly bond a thermoelectric material 412 to an electrode material 410. In FIG. 4, electrode material 410 and thermoelectric material 412 are positioned inside die 414. Die 414 can comprise, for example, a cylindrical cavity formed within a bulk material. In certain embodiments, the bulk material from which the die is formed comprises an electrically conductive material (e.g., having an electrical resistivity of less than about 1×10⁻⁵ ohm-m, less than about 1×10⁻⁶ ohm-m, or less than about 1×10⁻⁷ ohm-m at 20° C.), such as graphite, a high melting point metal (e.g., a superalloy), an electrically conductive ceramic, or any other suitable electrically conductive material.

Compression can be applied to electrode material 410 and thermoelectric material 412 via plungers 418, for example, in the direction of the arrows in FIG. 4. Plungers 418 can be formed of an electrically conductive material, including any of the electrically conductive materials described above with respect to die 414. In certain embodiments, electrically insulating plugs 416 can be positioned between plungers 418 and the material that is to be pressed (e.g., electrode material 410 and thermoelectric material 412 in FIG. 4).

In certain embodiments, bonding between electrode material 410 and thermoelectric material 412 can be achieved by applying a voltage across plungers 418, and producing heat via Joule heating. In certain embodiments, when a voltage is applied across plungers 418, electrical current is transported through one plunger, through die 414, and to the other plunger, causing Joule heating within the plungers and the die. In some such embodiments, the heat produced within plungers 418 and die 414 can be transferred to thermoelectric material 412 and/or the electrode material 410, which, in combination with an applied pressure, can be used to form a bond between the electrode material and the thermoelectric material.

The thermoelectric devices described herein can be used in a variety of applications. For example, in certain embodiments, inventive thermoelectric devices can be used as heat engines, converting thermal gradients into electricity. For example, inventive thermoelectric systems can be used to convert thermal gradients in geothermal heating systems, solar heating systems, and the like into electricity. Inventive thermoelectric devices described herein can also be used to provide localized cooling. The following examples are intended to illustrate certain embodiments of the present invention, but do not exemplify the full scope of the invention.

### EXAMPLE 1

This examples describes the integration of skutterudite-based thermoelectric materials with electrode materials for use in thermoelectric devices. Skutterudite materials were used to form n-type and p-type thermoelectric materials. The composition of the n-type material was Yb_{0.35}Co₄Sb₁₂while composition of the p-type material was NdFe_{3.5}Co_{0.5}Sb₁₂. The properties of the n-type and p-type compositions used in the examples were measured by Jian Yang, as described in his Ph.D. thesis entitled “Thermoelectric Properties of CoSb₃-Based Skutterudites” (Boston College, Graduate School of Arts & Sciences, 2010). The n-type thermoelectric material exhibited a peak ZT value of 1.2 at 550° C., and the p-type material exhibited a peak ZT value of 0.8 at 550° C.

Electrodes were fabricated using cobalt silicide electrode materials. CoSi₂ was used as the electrode material for bonding to the n-type thermoelectric material. Co₂Si was used as the electrode material for bonding with the p-type thermoelectric material. The cobalt silicides had coefficients of thermal expansion (CTEs) that were well matched with the skutterudite thermoelectric materials. In addition, the cobalt silicides exhibited high thermal and electrical conductivities. The bonds between the cobalt silicides and the thermoelectric materials exhibited low electrical and thermal contact resistances. The bonds between the cobalt silicides and the skutterudite-based thermoelectric materials were also expected to be chemically stable over the lifetime of a typical thermoelectric device (e.g., about 10 years).

CoSi₂ electrode material was made using a direct hot press method. CoSi₂ powder was procured from Alpha Aesar and pressed at 1200° C. for 3 min at 84 MPa (0.35 ton force). The measured density was 4.9 g/cm³. It was clear by inspection with an optical microscope that there were macroscopic void spaces within the material, and it is believed that adding trace amounts of Ni or B to the powder may help achieve full density. Co₂Si electrode material was made by the melt method, ball-milled into a powder and pressed at 1100° C. for 3 min at 70 MPa. The measured density of the Co₂Si electrode material was 7.1 g/cm³. The Co₂Si electrode material exhibited no macroscopic or microscopic voids. Both CoSi₂ and Co₂Si samples were then annealed at 1000° C. for 10 hrs before being cut and polished into disks.

Device samples (i.e., electrodes bonded to skutterudite thermoelectric material) were fabricated using a hot press method in which the electrodes were directly bonded to the skutterudite material via the application of pressure and heat. A press similar to press 400 illustrated in FIG. 4 was used to bond the skutterudite thermoelectric material to the electrode material. In the direct bonding method, rigid electrodes and thermoelectric material powder were placed inside a cylindrical cavity of a graphite die (similar to die 414 in FIG. 4). The electrodes and thermoelectric material were arranged in a similar fashion to the electrode material 410 and thermoelectric material 412, respectively, illustrated in FIG. 4. Cylindrical electrically insulting plugs (similar to plugs 416 in FIG. 4) having a height of 7 mm were made from a machinable glass (Macor) with a thermal conductivity of 1.5 W/mK, relatively low compared to that of the graphite (about 100 W/mK). Cylindrical plungers (similar to plungers 418 in FIG. 4) were used to apply pressure to the sample during heating. Thermoelectric material powder was included at the top and bottom of the samples as a getter material to absorb oxygen diffusing through the plunger-die gap during the pressing process.

After the materials were arranged as illustrated in FIG. 4, a voltage was applied across the plungers such that electrical current was passed from one of the plungers, through the graphite die, and through the second plunger. When operated in this fashion, substantially no current was passed through the electrode material and the thermoelectric material powder. Passage of electrical current through the plungers and the die generated heat via joule heating.

During the heating step, the temperature of the sample (i.e., the thermoelectric material and the electrode material) equilibrated to a value relatively close to the temperature of the die (T_{die}) because the sample was thermally insulted from the relatively hot plungers and there was no substantially no joule heating in the sample (due to the substantial absence of current passing through the sample). This arrangement generally allowed one to heat the system rapidly via joule heating, cool the system rapidly via conduction of heat through the die, and to achieve excellent temperature uniformity through the die and sample. Generally, the temperature inside the sample was uniform and differed from the die temperature by only 0.4-5° C.

During the pressing step, the thermoelectric powder sintered to itself and to the electrodes, producing a bond with superior mechanical, electrical, and thermal contact.

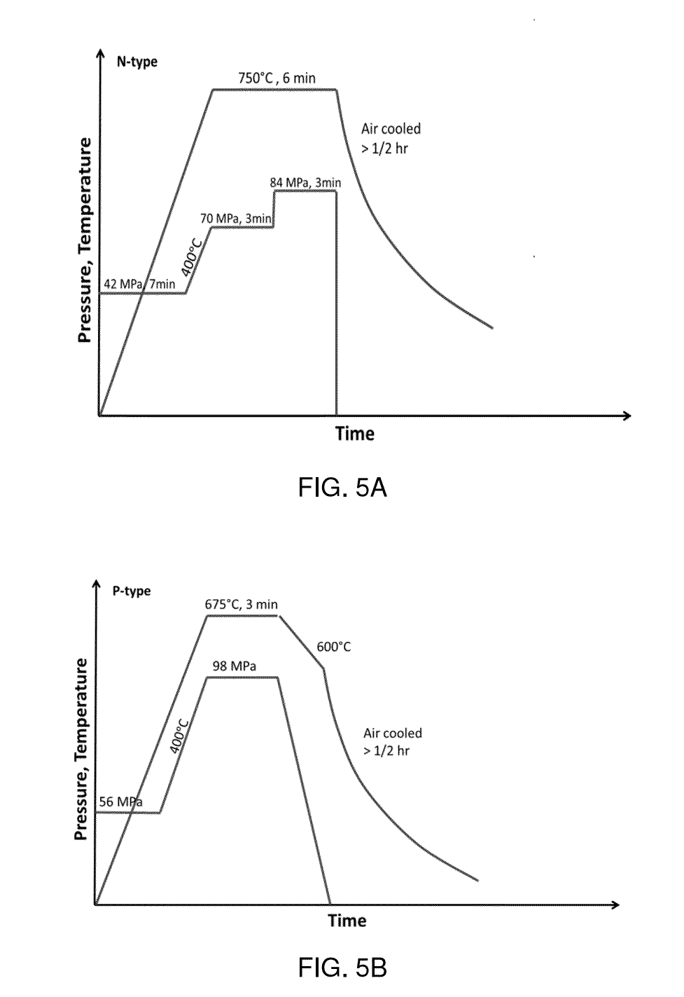

FIG. 5A is a plot of temperature and pressure as a function of time, outlining the processing conditions for pressing the n-type samples. Initially, a pressure of 42 MPa was applied at room temperature, enough to compress the powder by 1-2 mm and reduce oxygen gas permeability but low enough to avoid fracturing the electrodes. At the beginning of the press, the exposed section of the plunger was relatively long, and if too much current was provided, the plunger could overheat and fail. A constant current was set so that the plunger glowed red but not too brightly. Voltages of between about 2 V and about 4 V were applied across the die. Onset of sintering occurred at 400° C., and from that point forward, the current was slowly increased as the sample compressed. The n-type thermoelectric material was sintered at a relatively high temperature/pressure/time of 750° C./6 min/84 MPa to achieve a higher density and low contact resistance.

FIG. 5B is a plot of temperature and pressure as a function of time, outlining the processing conditions for pressing the p-type samples. The p-type samples were pressed at a lower temperature and time of (675° C. /3 min/98 MPa) to limit mass diffusion at the interface and produce a smaller contact resistance. The p-type samples were more prone to cracking than the n-type samples, so cooling was performed at a controlled rate at of about 20 K/min while simultaneously reducing the pressure until the sample reached 600° C. Once the sample reached 600° C., it was removed from the press and allowed to cool in air.

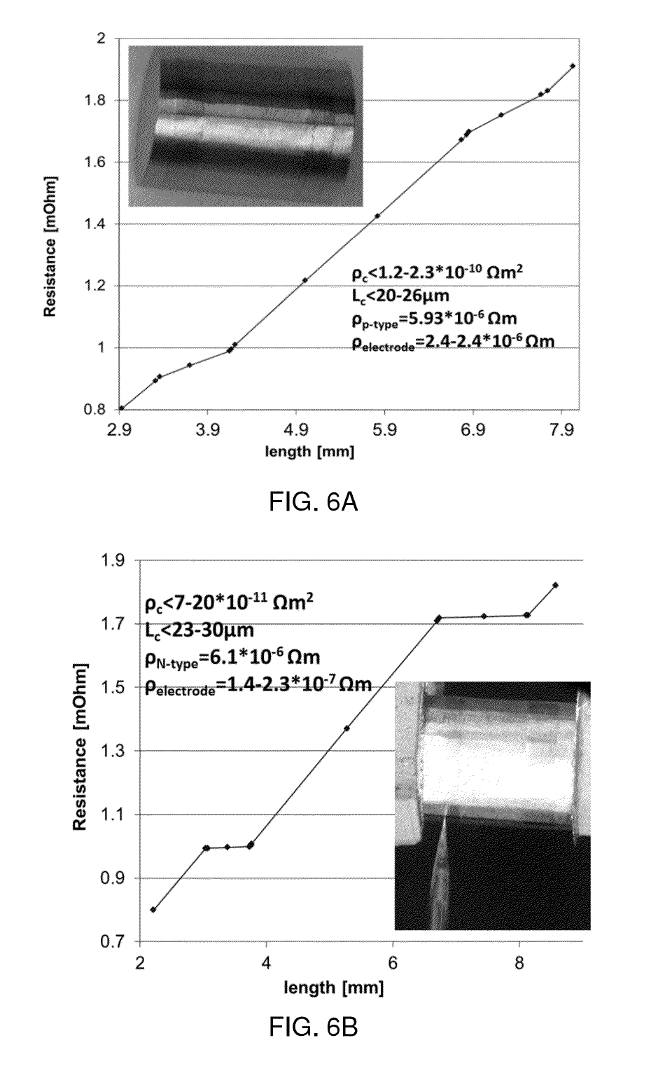

After the press process was performed, the samples were polished and inspected for cracks. The device samples were then cut along their longitudinal axes into four pieces each. The bulk electrical resistivities and contact resistances of two pieces (each as a function of length) for each sample were tested. FIGS. 6A and 6B are plots of the bulk resistivity and of the contact resistance, respectively, of the samples. The bulk resistivity values were within the expected range and the samples showed no sign of cracks at the mid-plane. The electrical contact resistance was measured by wetting the samples with In—Ga eutectic (liquid metal), injecting current on each end of the sample, and making a 4-wire measurement. The values shown in FIG. 6B are an upper limit estimate. The p-type thermoelectric material exhibited an electrical resistivity of 1.2-2.3e−10 Ωm² and constituted 1.5-2.9% of the total resistance of the leg. The n-type thermoelectric material had an electrical resistivity of 0.7-2.0e−10 Ωm² and constituted 0.8-2.2% of the total resistance of the leg.

### EXAMPLE 2

This example describes thermoelectric testing of the n-type and p-type thermoelectric legs, including electrode material bonded to thermoelectric material, fabricated as described Example 1.

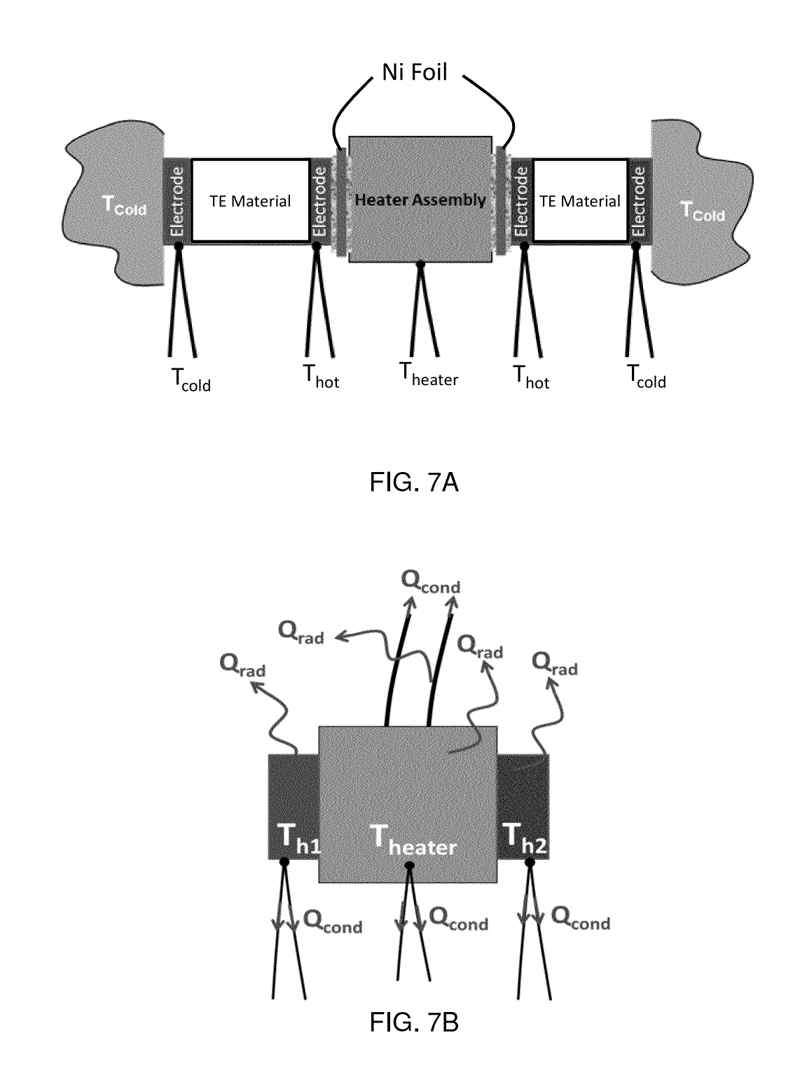

FIG. 7A is an exemplary schematic diagram illustrating a typical inline device measurement system used to test n-type and p-type thermoelectric materials. An axial force was applied to hold the legs in compression. Current and heat were passed horizontally through the legs and approximated as 1-D transport. Heat was generated in the middle at the heater assembly to raise its temperature to 600° C. while the ends were maintained near room temperature (T_{cold} in FIG. 7A). Testing was conducted on a cryostat in vacuum to eliminate air convection. However, radiation losses were still present at the heater and on the sides of the legs. Cold water was passed through the cryostat cold finger to maintain the cold side temperature. The overall length of the device in FIG. 7A was 13 mm.

Two thermocouples on each leg were used to measure T_{cold} and Tₕₒₜ. In addition, a thermocouple was used to measure the temperature of the heater (Tₕₑₐₜₑᵣ). The thermovoltage between each thermocouple junction was also measured. The ZT measurement was performed by setting a heater voltage, allowing the system to come to steady state and then measuring three device properties: Qₕₒₜ entering the legs, the open circuit Seebeck voltage of each leg, and the electrical resistance of each leg. The ZT measurement was taken between the thermocouples and included heat losses at the sides of the legs, electrical contact resistance, and parasitic thermal/electrical resistances in the electrodes between the interface and thermocouples across a distance L_{TC-interface}=0.35 mm.

The thermocouples were type K with a diameter of 2 mils. They were attached to the electrodes with silver epoxy. Upon raising the hot side to 260° C. the organics would bake off leaving the thermocouple bead embedded in a sintered Ag matrix. Calibration tests confirmed that the thermocouples produced accurate temperature readings.

It was determined that platinum was the most effective material for measuring the Seebeck coefficient, as it was extremely stable with repeatable transport properties. Accordingly, two platinum wire leads were connected to the hot copper block and thermocouples near room temperature on the cold side.

A custom-built heater was designed and used in the tests. To fabricate the heater, two slots were milled into a 3×3×3 mm copper block, and the side walls were polished to minimize the emissivity. A platinum RTD (from Omega engineering) was inserted into each slot and filled with braze (45Ag₂₇Cu₂₅Zn₃Sn braze, Tₘₑₗₜ=641-682° C.). Current was supplied by 2 mil Pt wire, 25 mm in length, which were brazed to the electrical leads. A type K, 2 mil, thermocouple was attached to measure Tₕₑₐₜₑᵣ.

Legs of thermoelectric materials (labeled “TE materials” in FIG. 7A) were mounted in an inline configuration and held in compression. The surfaces were polished to reduce their emissivity. The thermocouples were 35 mm long and attached to the electrodes about 0.35 mm from the interface with silver epoxy and cured at 120° C. for 8 hrs. A 12.5 μm layer of Ni foil was inserted in-between the hot electrode and Cu heater block and bonded with Ag epoxy, which protected the electrode from Cu diffusion. Once the legs and heater were loaded, the thermocouple wires were wrapped around their respective terminals and the heater electrodes were soldered to their terminals.

An energy balance was performed on the system. FIG. 7B is a schematic diagram illustrating the various pathways for thermal loss in the system. The total hot side heat is calculated as:

Q_{Hot}=IV_{Heater}−Q_{loss,Pt}−Q_{loss,TC}−Q′_{Heater}−Q_{electrodes} [6]

wherein Q′_{Heater} is the total heat loss at the heater surface and is calculated as:

Q′_{Heater}=A_{Heater}(e₀+e_{T}Tₕₑₐₜₑᵣ)(Tₕₑₐₜₑᵣ⁴−T_{∞}⁴)+A_{Heater}U(Tₕₑₐₜₑᵣ−T_{∞}) [7]

where A_{Heater} is the surface area of the heater that is exposed to the external environment, and T_{∞} is the temperature of the ambient atmosphere at a location far away from the heater. Q′_{Heater} was modeled using a temperature-dependent emissivity of the form:

e=(e₀+e_{T}Tₕₑₐₜₑᵣ) [8]

and a convection coefficient U. The three constants e₀ (=0.1822), e_{T} (=7.9×10⁻⁵), and U (=−0.0033) were solved for by least squares regression with the measured IV_{Heater} data. The regression exhibited an excellent fit. The magnitude of the convection coefficient was negligibly small, providing further evidence that the vacuum was effective in suppressing air conduction and that the wire losses were calculated accurately. The resulting average emissivity at low temperature (65° C.) and high temperature (625° C.) were 0.209 and 0.253, respectively. The experimentally measured and calculated Q_{Heater} values were similar.

The electrodes were modeled as isothermal with a constant emissivity at the temperature measured by each hot side thermocouple. FTIR (Fourier Transform Infrared Spectroscopy) was used to measure the emissivity of the electrode and skutterudite surfaces after completing the ZT testing. (The surface properties visually change after exposed to high temperature testing due to Sb sublimation and oxidation so it was more appropriate to measure the surface properties after ZT testing rather than before.) The emissivities (emissivity=1−reflectance) of the various materials were as follows: n-type=0.7; p-type=0.6; CoSi₂=0.2; and Co₂Si=0.5. The largest thermal losses were from the heater, at about 7% of IVₕₑₐₜₑᵣ. Losses from the electrodes were about 4.4% of IVₕₑₐₜₑᵣ at high temperature.

A thermal correction factor was calculated, which corresponded to the amount that the raw heater power was adjusted by to account for thermal losses. The thermal correction factor was calculated as follows:

$$Correction Factor = \frac{{IV}_{heater} - {Q}_{Hot}}{{IV}_{Hot}} \qquad [ 9 ]$$

The maximum total correction factor of the N-N test was 12.4%, and for the P-P test was 21%. The P-P system had a larger thermal loss correction because the emissivity of Co₂Si is greater than CoSi₂, and the magnitude of IVₕₑₐₜₑᵣ was smaller due to a smaller thermal conductivity.

N-Type/N-Type Testing

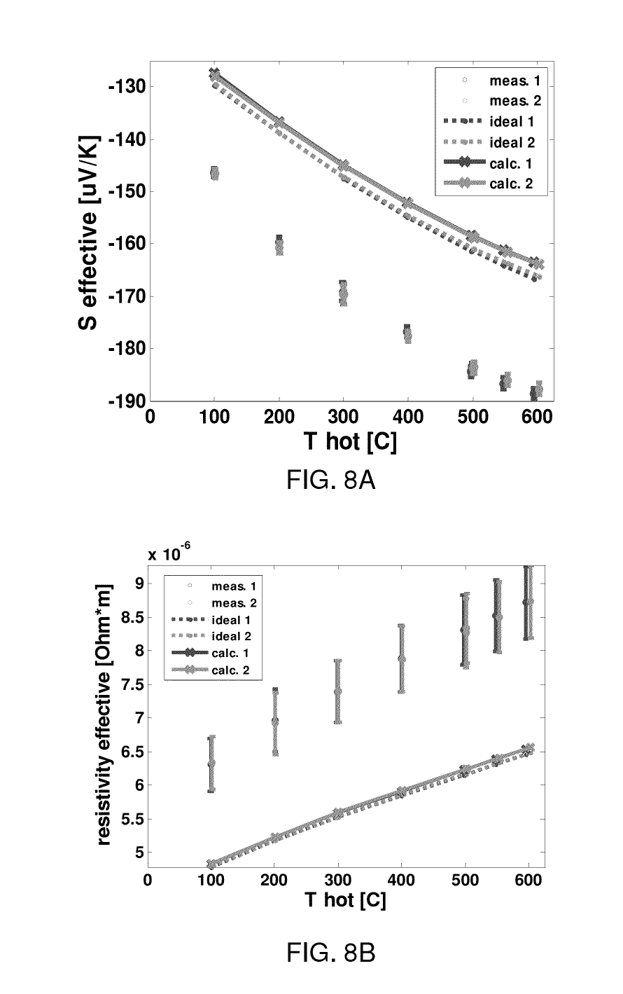

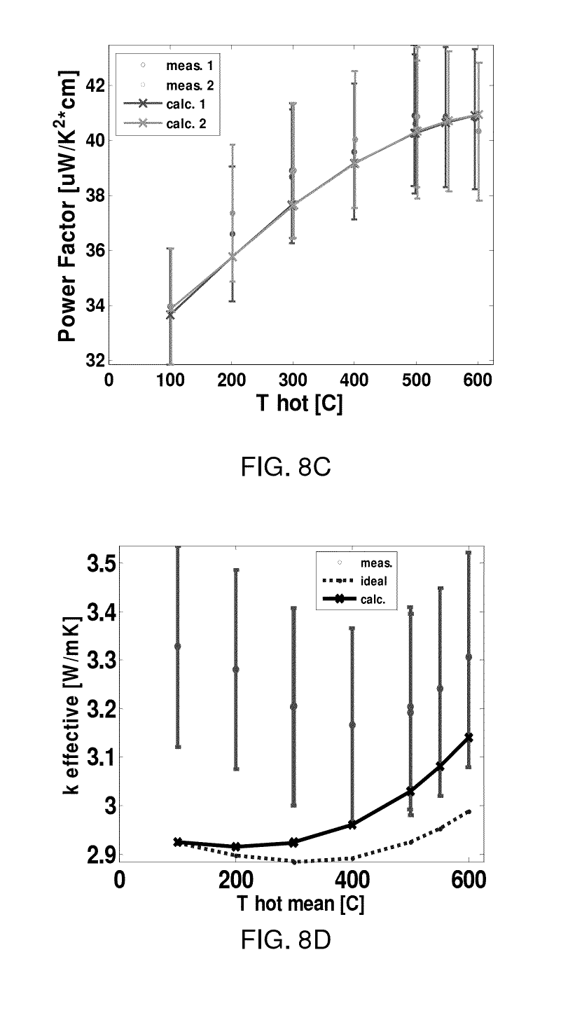

A device was fabricated in which two n-type legs of thermoelectric material were assembled as illustrated in FIG. 7A and tested according to the methods outlined above. FIGS. 8A-D are plots of the measured n-type effective properties and the effective power factor along with the calculated values. The “calc.” values were calculated with by using the corresponding geometry, temperature dependent thermoelectric properties, and emissive properties of the skutterudite and electrode, the “ideal” values only use the geometry and temperature dependent properties of the skutterudite.

The magnitude of the effective Seebeck was much higher than expected. In addition, the resistivity was also much higher than expected. Without wishing to be bound by any particular theory, this may have been due to different carrier concentrations between the device samples and individual property measurements. The measured power factor was similar to the calculated values. It is common for the Seebeck and resistivity to be different from batch to batch but produce similar power factors.

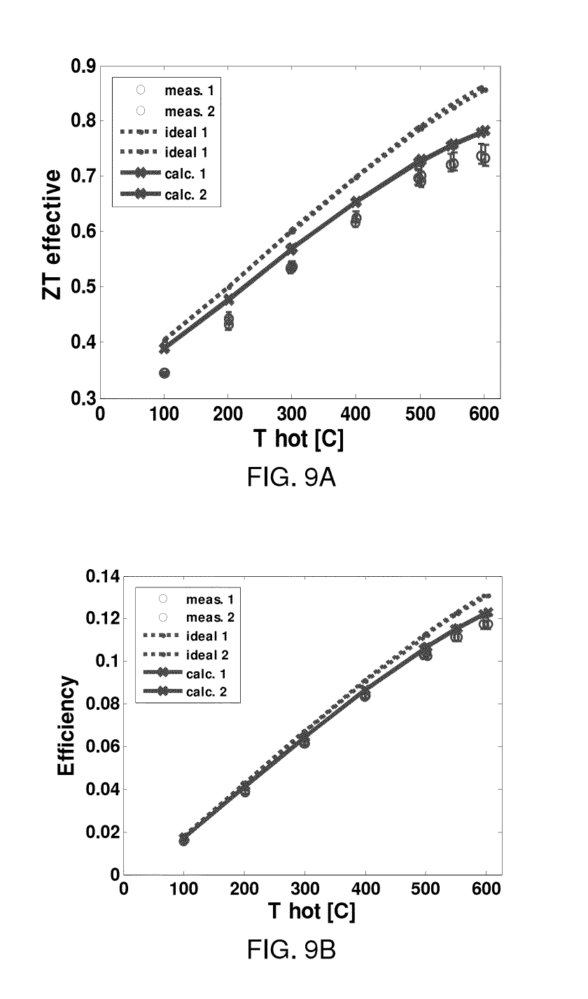

FIGS. 9A-B are plots of ZT and the corresponding maximum efficiency. The highest measured ZT was 0.74 at 595° C. on the hot side and 52° C. on the cold side; this corresponds to a maximum conversion efficiency of 11.7%. The maximum calculated efficiency was 12.2% compared to an ideal efficiency of 13.1%. Thus the parasitic losses have degraded the efficiency by 0.9 efficiency points or reduced the power by 7%.

P-Type/P-Type Testing

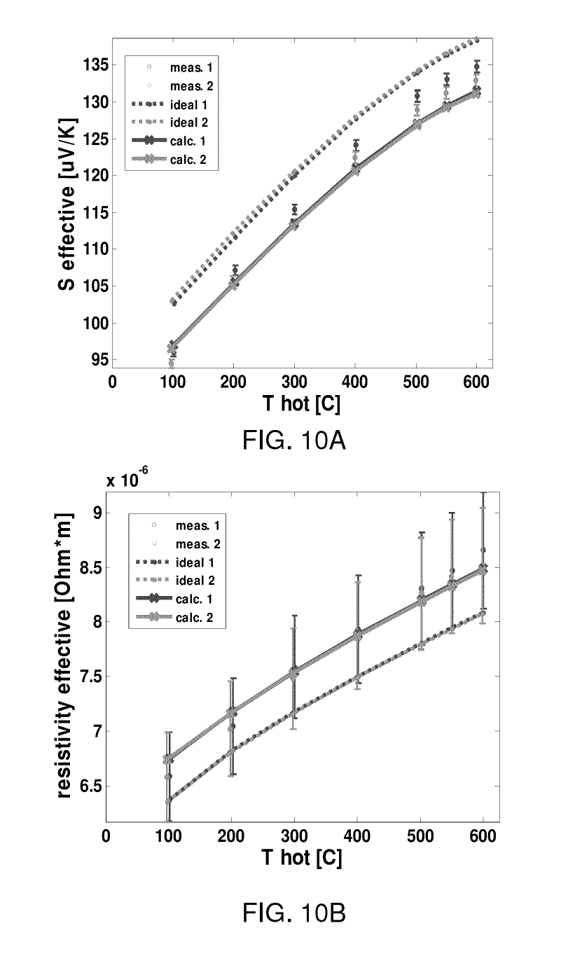

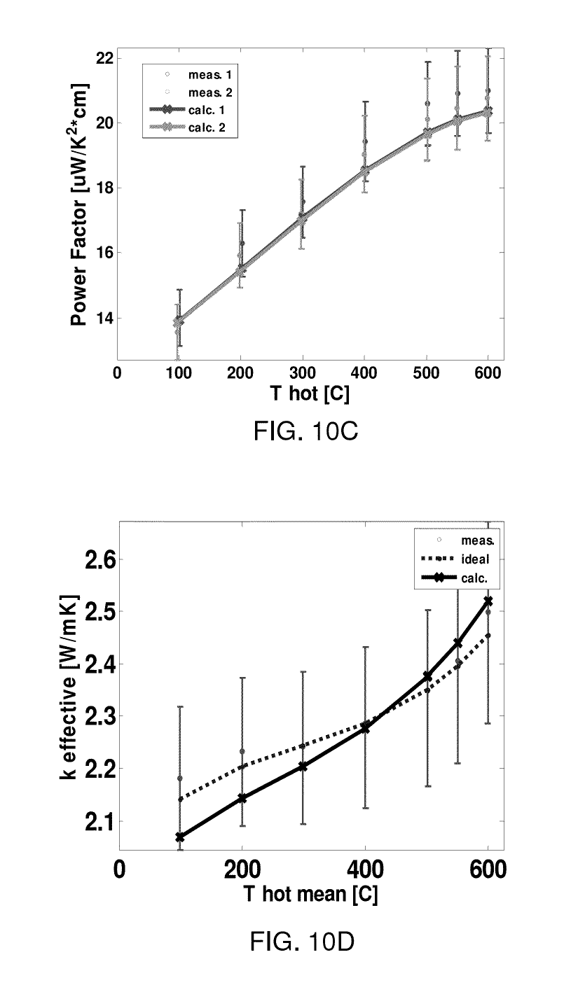

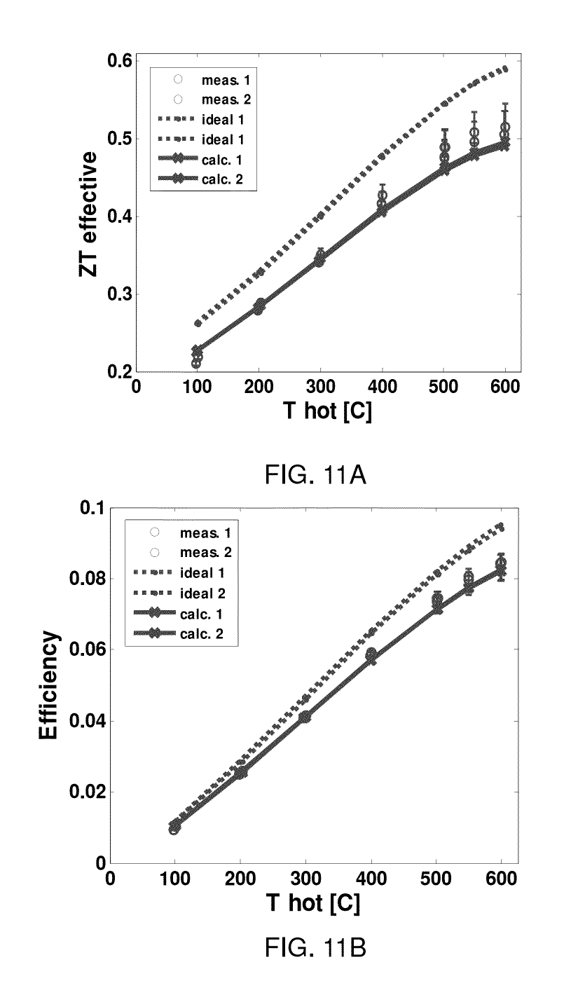

A device was fabricated in which two p-type legs of thermoelectric material were assembled as illustrated in FIG. 7A and tested according to the methods outlined above. FIGS. 10A-D are plots of the measured p-type effective properties and the effective power factor along with the calculated values. The measured property values were in very good agreement with the calculated values. FIGS. 11A-B are plots of ZT and the corresponding maximum efficiency. The highest measured ZT value was 0.51 at 600° C. on the hot side and 77° C. on the cold side. This corresponds to a maximum conversion efficiency of 8.5%. The maximum calculated efficiency was 8.2% compared to an ideal efficiency of 9.4%. Thus the parasitic losses have degraded the efficiency by 1.2 efficiency points or reduced the power by 13%.

N-Type/P-Type Testing

A device was fabricated in which a p-type leg of thermoelectric material and an n-type leg of thermoelectric material were assembled as illustrated in FIG. 7A. The power and conversion efficiency of the assembled device was then measured.

The power produced by each leg can be calculated by multiplying the voltage gain in the direction of current flow by the current, as follows:

Pₑ=I·V_{TE,N}+I·V_{TE,P} [10]

The thermoelectric voltage was measured between the thermocouples mounted on each electrode. The power was measured as if the electrodes were joined to each other with zero contact resistance, and the parasitic electrical resistance at the heater assembly was separated from the measurement.

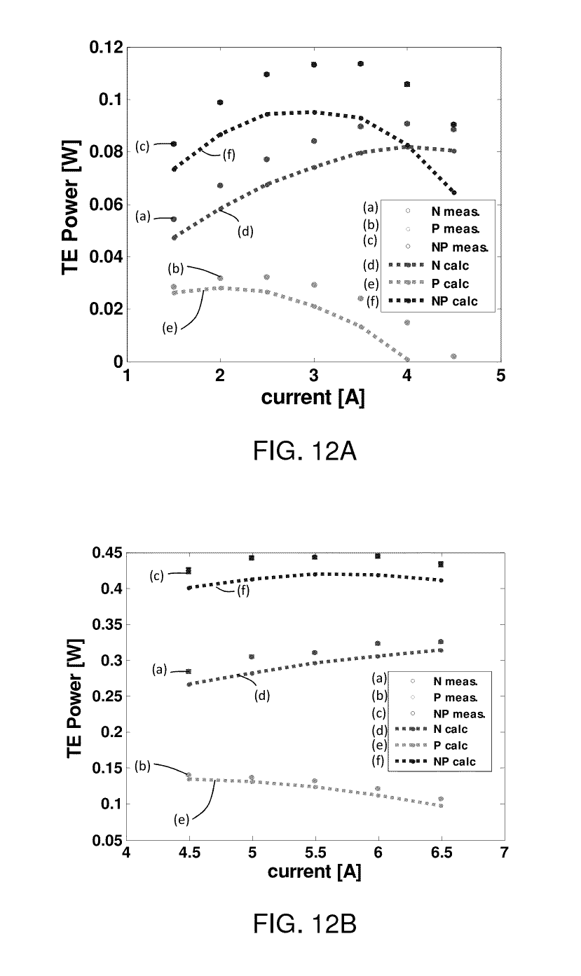

The measured power and calculated power versus current are plotted in FIGS. 12A-B for two different temperature ranges. In the higher temperature range (the results of which are plotted in FIG. 12B), the n-type and p-type legs operated between 558-559° C. and 544-546° C., respectively, on the hot side and 58-63° C. and 76-83° C. on the cold side. The maximum power produced was 0.445 W at 6 A. In the lower temperature range (the results of which are plotted in FIG. 12B), the n-type and p-type legs operated between 302-306° C. and 295-298° C., respectively, on the hot side and 39-43° C. and 48-54° C. on the cold side. The maximum power produced was 0.114 W at 3.5 A. The power of the individual legs peaked at very different current values, indicating that the geometry is not well matched to maximize the efficiency or power of the unicouple. It is believed that the efficiency and power of the unicouple could be further enhanced by properly matching the geometries of the n-type and p-type thermoelectric materials.

The conversion efficiency of the device was also determined. The heat entering the legs was measured in the same way as the effective properties with the addition of joule heating at the heater assembly:

Q_{Hot}=Q_{Hot,I=0}+I|Vₑ₁|+I|Vₑ₂| [11]

where Vₑ₁ and Vₑ₂ are the voltages between the electrodes and the heater. The measured efficiency was calculated as:

η=Pₑ/Q_{Hot} [12]

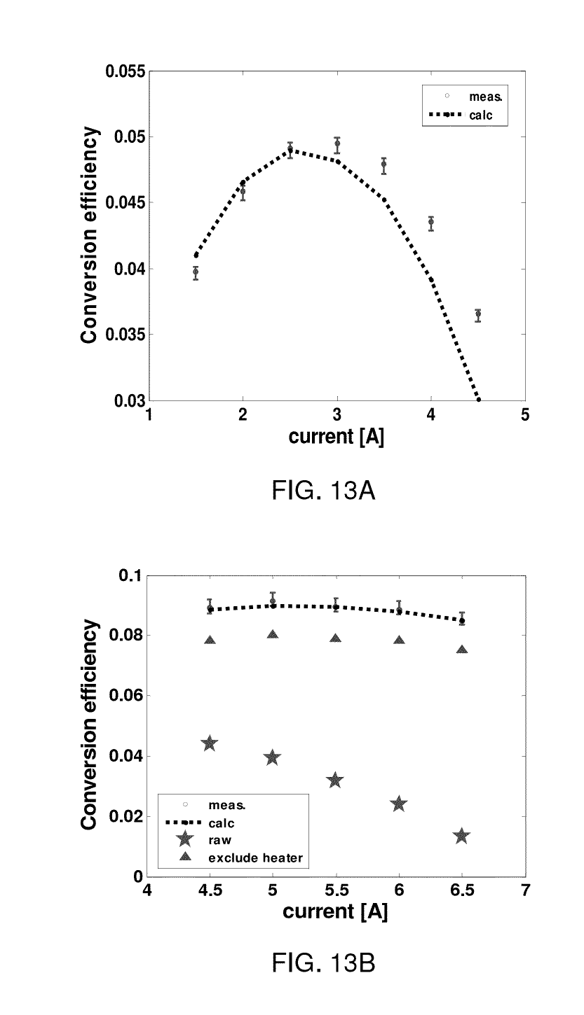

FIGS. 13A-B are plots of conversion efficiency as a function of current. In FIG. 13A, the hot side temperature of the N and P legs were at 302-306° C. and 295-298° C., respectively, and the cold side was at 39-43° C. and 48-54° C. In FIG. 13B, the hot side temperature of the N and P legs were at 558-559° C. and 544-546° C., respectively, and the cold side was at 58-63° C. and 76-83° C. In FIGS. 13A-13B, the “meas.” and “calc.” values are the final values after the heater section has been excluded thermally and electrically.

The maximum measured efficiency in the lower (FIG. 13A) and higher (FIG. 13B) temperature range was 5.0% and 9.1% respectively. The thermal correction factor (Qₗₒₛₛ/IVₕₑₐₜₑᵣ) was 12.5%.

In FIG. 13B, the green triangles represent the case in which the heater was not thermally excluded from the measured result (i.e., the thermal correction factor, described above in Equation 9, was not applied for these data points). The purple stars represent the case in which the heater assembly was not excluded thermally or electrically, which corresponds to the efficiency that is determined if the voltage is measured between T_{c1} and T_{c2} and there is no correction for thermal losses.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

What is claimed is:

1. A thermoelectric device, comprising:
an electrode material comprising silicon; and
a thermoelectric material in electronic communication with the electrode material, wherein the absolute value of the Seebeck coefficient of the thermoelectric material is at least about 10 μV/K at at least one temperature lower than about 600° C.

2. The thermoelectric device of claim 1, wherein the absolute value of the Seebeck coefficient of the thermoelectric material is from about 10 μV/K to about 500 μV/K at at least one temperature lower than about 600° C.

3. The thermoelectric device of claim 1, wherein the electrode material further comprises at least one of cobalt, chromium, iron, and nickel.

4. The thermoelectric device of claim 3, wherein silicon, cobalt, chromium, iron, and/or nickel make up at least about 75% of the electrode material, by mass.

5. The thermoelectric device of claim 1, wherein the electrode material comprises a cobalt silicide.

6. The thermoelectric device of claim 1, wherein the thermoelectric material comprises at least one of As, P, and Sb.

7. The thermoelectric device of claim 6, wherein the thermoelectric material comprises Sb.

8. The thermoelectric device of claim 1, wherein the thermoelectric material comprises at least one of Co, Cr, Ni, and Fe.

9. The thermoelectric device of claim 1, wherein the thermoelectric material comprises at least one of Yb, Nd, La, Ce, Pr, Pm, Sm, Eu, Gd, Tb, Dy, Ho, Er, Tm, and Lu.

10. The thermoelectric device of any one of claim 1, wherein the thermoelectric material comprises a skutterudite material.

11. The thermoelectric device of claim 10, wherein the thermoelectric material comprises at least one of Yb, Nd, Fe, Co, and Sb.

12. The thermoelectric device of claim 11, wherein the thermoelectric material comprises NdₐFe_{b1}Co_{b2}Sb_{c}, wherein:
a is from about 0 to about 1;
b1 is greater than 0;
b2 is greater than 0;
the sum of b1 and b2 is from about 3.5 to about 4.5; and
c is from about 11.5 to about 12.5.

13. The thermoelectric device of claim 12, wherein the thermoelectric material is p-doped.

14. The thermoelectric device of claim 11, wherein the thermoelectric material comprises YbₐCo_{b}Sb_{c}, wherein:
a is from about 0 to about 1;
b is from about 3.5 to about 4.5; and
c is from about 11.5 to about 12.5.

15. The thermoelectric device of claim 14, wherein the thermoelectric material is n-doped.

16. The thermoelectric device of claim 1, wherein at least a portion of the electrode material is in direct contact with at least a portion of the thermoelectric material.

17. The thermoelectric device of claim 1, wherein an intermediate material is positioned between at least a portion of the electrode material and at least a portion of the thermoelectric material.

18. The thermoelectric device of claim 1, wherein the electrode material is in electronic communication with a second thermoelectric material.

19. A thermoelectric device, comprising:
an electrode material comprising silicon; and
a thermoelectric material in electronic communication with the electrode material, wherein the thermoelectric material exhibits a Thermoelectric Figure of Merit of at least about 0.5 at at least one temperature lower than about 600° C.

20. The thermoelectric device of claim 19, wherein the thermoelectric material exhibits a Thermoelectric Figure of Merit of from about 0.5 to about 3 at at least one temperature lower than about 600° C.
